(19) United States
(12) Patent Application Publication
(10) Pub. No.: US 2015/0256179 A1
(43) Pub. Date: Sep. 10, 2015

(54) SWITCHING CONTROL CIRCUIT AND WIRELESS COMMUNICATION DEVICE

(71) Applicant: KABUSHIKI KAISHA TOSHIBA, Tokyo (JP)

(72) Inventors: Kazunobu KATOU, Kisarazu Chiba (JP); Toshiki SESHITA, Kawasaki Kanagawa (JP)

(21) Appl. No.: 14/474,306

(22) Filed: Sep. 2, 2014

(30) Foreign Application Priority Data
Mar. 6, 2014 (JP) 2014-044119

(51) Int. Cl. H03K 19/0175; H04B 15/00; H04B 1/401

(52) U.S. Cl. CPC H03K 19/0175; H04B 1/401; H04B 15/005; H04W 88/06

(57) ABSTRACT

A switching control circuit includes a level shifter that generates a switching control signal for a switching circuit, and a voltage generation circuit. The voltage generation circuit includes a first oscillator that generates a first oscillating signal, a frequency spectrum of which is controlled to be spread spectrum based on a second oscillating signal different from the first oscillating signal, and a power supply circuit that generates a power supply voltage based on the first oscillating signal and supplies a converted power supply voltage to the level shifter.

### CROSS-REFERENCE TO RELATED APPLICATION

This application is based upon and claims the benefit of priority from Japanese Patent Application No. 2014-044119, filed Mar. 6, 2014, the entire contents of which are incorporated herein by reference.

### FIELD

Embodiments described herein relate generally to a switching control circuit which performs switching of a switching circuit, a semiconductor device, and a wireless communication device.

### BACKGROUND

In mobile communication devices such as the latest smart phone, or a mobile phone, there are many mobile communication devices that comply with a wireless communication standard such as the third generation (3G), which is referred to as a Universal Mobile Telecommunications System (UMTS), and the fourth generation (3.9G), which is referred to as a Long Term Evolution (LTE), which further speeds up data communication of the 3G, in addition to a Global System for Mobile Communications (GSM®) system. In order to deal with these wireless systems, it is necessary to provide a high frequency semiconductor switching circuit that performs switching of a plurality of high frequency input-output terminals such as Single-Pole 8-Throw (SP8T), for example, in a mobile communication device.

In the high frequency semiconductor switching circuit, a circuit portion that switches a wireless signal at high speed and a circuit portion that performs a digital logic operation, coexist, and performing level conversion of a signal is necessary when the signal is transmitted or received between circuits. To perform the level conversion, a plurality of power supply voltages is necessary. In general, a plurality of power supply voltages is generated by stepping up or stepping down a reference voltage using an oscillator and a power supply circuit.

However, in the case of the UMTS system, for example, since reception is performed in a predetermined frequency bandwidth that is close to a transmission frequency, a normal reception may not be possible due to interference with a reception signal by higher harmonic components of an oscillating signal used for driving the power supply circuit.

### DESCRIPTION OF THE DRAWINGS

FIG. 1 is a block diagram which illustrates a schematic configuration a switching control circuit and a switching circuit according to one embodiment.

FIG. 2 is a circuit diagram which illustrates an example of an internal configuration of the switching circuit.

FIG. 3 is a circuit diagram which illustrates a first example of a level shifter in a driver unit.

FIG. 4 is a block diagram which illustrates an example of an internal configuration of a voltage generation circuit.

FIG. 5 is a diagram which illustrates a frequency spectrum of each signal in the switching control circuit and the switching circuit.

FIG. 6 is a diagram which illustrates a frequency spectrum of a high harmonic noise when an oscillating frequency of a first oscillating signal is constant.

FIG. 7 is a diagram which illustrates a spreading of a frequency spectrum.

FIG. 8 is a circuit diagram of a first example of an internal configuration of a first oscillator.

FIG. 9 is a circuit diagram which illustrates an example of an internal configuration of a second oscillator.

FIG. 10A is a diagram of a signal waveform of a second oscillating signal, FIG. 10B is a diagram of a signal waveform of a first oscillating signal when the second oscillating signal is input, and FIG. 10C is a diagram of a signal waveform of the first oscillating signal when the second oscillating signal is not input.

FIG. 11 is a circuit diagram which illustrates an example of the level shifter that performs stepping up of a power supply voltage on the high level side, and sets a power supply voltage on the low level side to a negative voltage.

FIG. 12 is a diagram which illustrates a second example of the internal configuration of the first oscillator.

FIG. 13 is a circuit diagram which illustrates a configuration of one step of inverters in a first ring oscillator.

FIG. 14 is a block diagram which illustrates a schematic configuration of a wireless communication device on which the switching control circuit and the switching circuit are mounted.

### DETAILED DESCRIPTION

Embodiments provide a switching control circuit that prevents an oscillating signal that is used for generating a power supply voltage from interfering with a reception signal, and a wireless communication device.

In general, according to one embodiment, there is provided a switching control circuit including a level shifter that generates a switching control signal for a switching circuit, and a voltage generation circuit that includes a first oscillator that generates a first oscillating signal, a frequency spectrum of which is controlled to be spread spectrum based on a second oscillating signal different from the first oscillating signal, and a power supply circuit that generates a power supply voltage based on the first oscillating signal and supplies a converted power supply voltage to the level shifter.

Hereinafter, an embodiment is described with reference to drawings. In the following embodiment, characteristic configurations and operations in the switching control circuit and the wireless communication device are mainly described, however, there may be omitted configurations and operations of the switching control circuit and the wireless communication device in the following descriptions. These omitted configurations and operations are also included in a range of the embodiment.

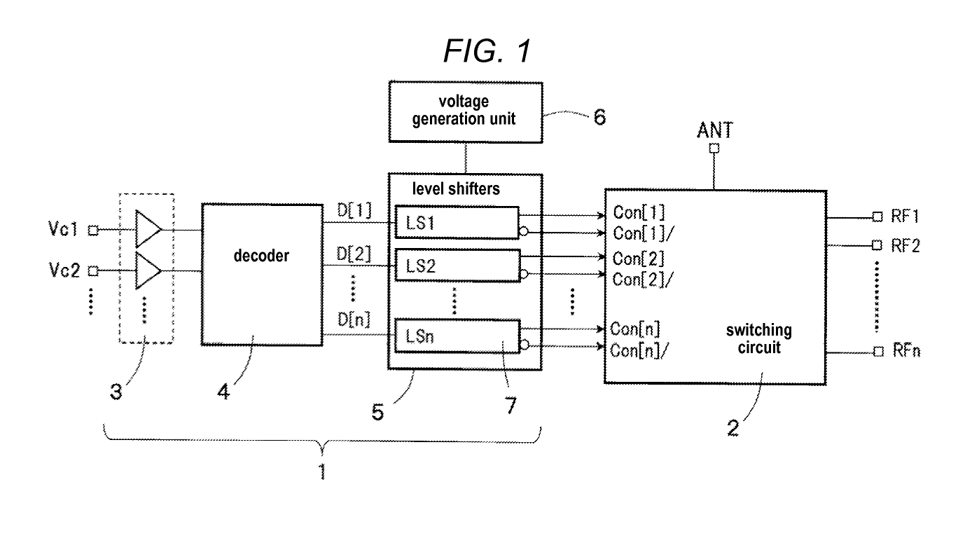

FIG. 1 is a block diagram which illustrates a schematic configuration of a switching control circuit 1 and a switching circuit 2 according to one embodiment. The switching control circuit 1 and the switching circuit 2 in FIG. 1 may be made into one chip by being integrally formed on a semiconductor substrate, or maybe configured as a plurality of semiconductor chips.

The switching control circuit 1 in FIG. 1 includes an input interface unit 3, a decoder 4, a driver unit 5, and a voltage generation circuit 6.

The input interface unit 3 includes a plurality of input buffers, each of which performs buffering with respect to each one of a plurality of switching control signals which are the inputs. The plurality of switching control signals is sent from a communication controller (not illustrated) which controls switching of a wireless system, for example.

The decoder 4 performs decoding of the plurality of switching control signals which are buffered in the input interface unit 3, and generates switching control data of n bits. Providing the decoder 4 can reduce the number of the plurality of switching control signals which are input to the input interface unit 3. In addition, the decoder 4 is not an essential constituent element, and may be omitted in some cases.

The driver unit 5 includes a plurality of level shifters 7 that perform a level conversion of each bit value of the switching control data. The signals whose level is converted using the plurality of level shifters 7 (switching control signal) are input to the switching circuit 2. In this manner, the driver unit 5 converts a signal level of the switching control data into a switching control signal with a voltage level that is suitable for a switching operation in the switching circuit 2.

The switching circuit 2 selects one of a plurality of high frequency signals RF1 to RFn based on the switching control signal, which is subject to the level conversion, and connects the signal to an antenna port ANT.

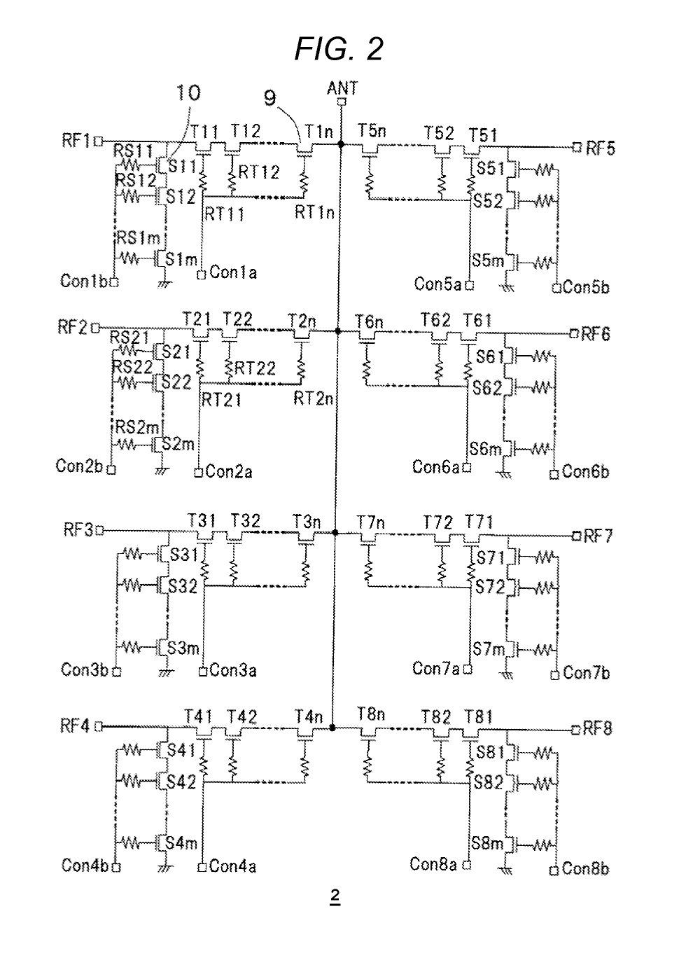

FIG. 2 is a circuit diagram illustrating an example of an internal configuration of the switching circuit 2. The switching circuit 2 in FIG. 2 is referred to as a Single-Pole 8-Throw (SP8T) switch. The SP8T switch performs a switching operation in which any one of eight RF ports RF1 to RF8 is electrically connected to the antenna port ANT according to switching control signals (Con1a and Con1b) to (Con4a and Con4b).

The SP8T switch in FIG. 2 includes a through FET 9 which is configured by connecting a plurality of FETs in series in multi-stages between the antenna port ANT and the respective eight RF ports of RF1 to RF8, and a shunt FET 10 which is configured by connecting the plurality of FETs in series in multi-stages between each RF port and a ground potential. A threshold voltage Vth of each FET is set to 0 V, for example.

The reason that the through FET 9 and the shunt FET 10 are connected in series in multi-stages is to reduce the voltage that is applied to each FET, since an input voltage amplitude is dozens of volts when performing transmission.

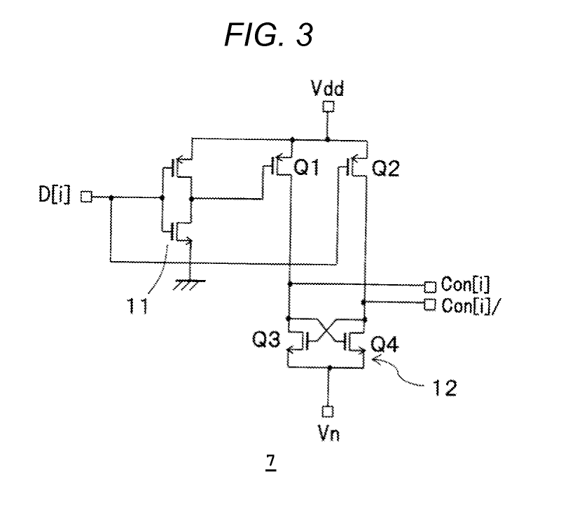

FIG. 3 is a circuit diagram which illustrates a first example of the level shifter 7 in the driver unit 5. The plurality of level shifters 7 corresponding to the plurality of switching control data items is provided in the driver unit 5, and the respective level shifter is configured using the same circuit as that in FIG. 3. The level shifter 7 in FIG. 3 performs level conversion using a first power supply voltage Vdd, which is a positive voltage and a second power supply voltage Vn, which is a negative voltage. The second power supply voltage Vn is generated in the voltage generation circuit 6. The first power supply voltage Vdd may be an external power supply voltage which is supplied to the switching control circuit 1 from the outside, and may be a voltage which is obtained by stepping down the external power supply voltage using a step-down regulator which is not illustrated.

The level shifter 7 in FIG. 3 includes an inverter 11, two PMOS transistors Q1 and Q2 whose the source side is connected to the first power supply voltage Vdd, and a voltage holding circuit 12 which includes two NMOS transistors Q3 and Q4 each having its gate is connected to the other's drain, and each having its source set to a ground potential.

The switching control data which is generated by the decoder 4 is sent to the level shifter 7 corresponding to each bit. The inverter in the level shifter 7 performs an inversion output of the switching control data.

For example, when the switching control data is high level, an output of the inverter 11 becomes a low level, the PMOS transistor Q1 is ON, and a high voltage level, which is close to the first power supply voltage Vdd, is output from Con [i]. At this time, since the PMOS transistor Q4 is in an ON state, the Con [i]/outputs a low voltage level, which is close to the second power supply voltage Vn.

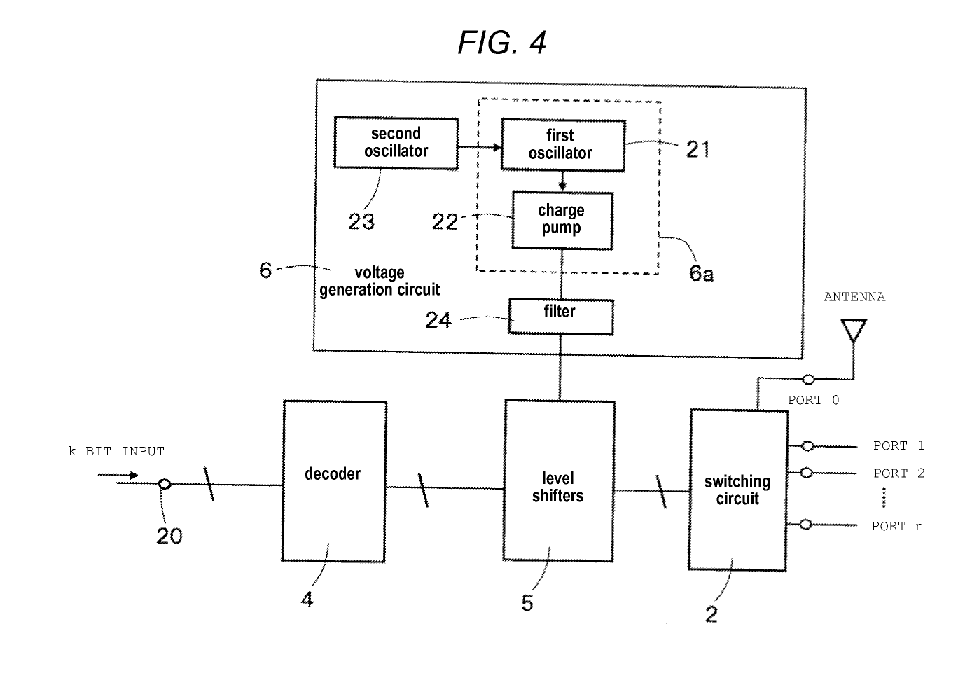

FIG. 4 is a block diagram which illustrates an example of an internal configuration of the voltage generation circuit 6. As illustrated, the voltage generation circuit 6 includes a first oscillator 21, a charge pump (power supply circuit) 22, a second oscillator 23. The first oscillator 21 and the charge pump 22 form a negative voltage generation circuit 6a. The first oscillator 21 generates a first oscillating signal whose oscillating frequency is subject to spread spectrum. The charge pump 22 performs a step-up operation or a step-down operation of a reference voltage based on the first oscillating signal. Since a voltage which is stepped up or stepped down by the charge pump 22 includes ripple components, the voltage is generated as a negative voltage by removing the ripple components using a filter 24. The generated negative voltage is supplied to each level shifter 7 in the driver unit 5. As is described later, the second oscillator 23 is used in order to continuously change the oscillating frequency of the first oscillator 21. In this manner, the voltage generation circuit 6 supplies to the level shifter 7 a converted power supply voltage.

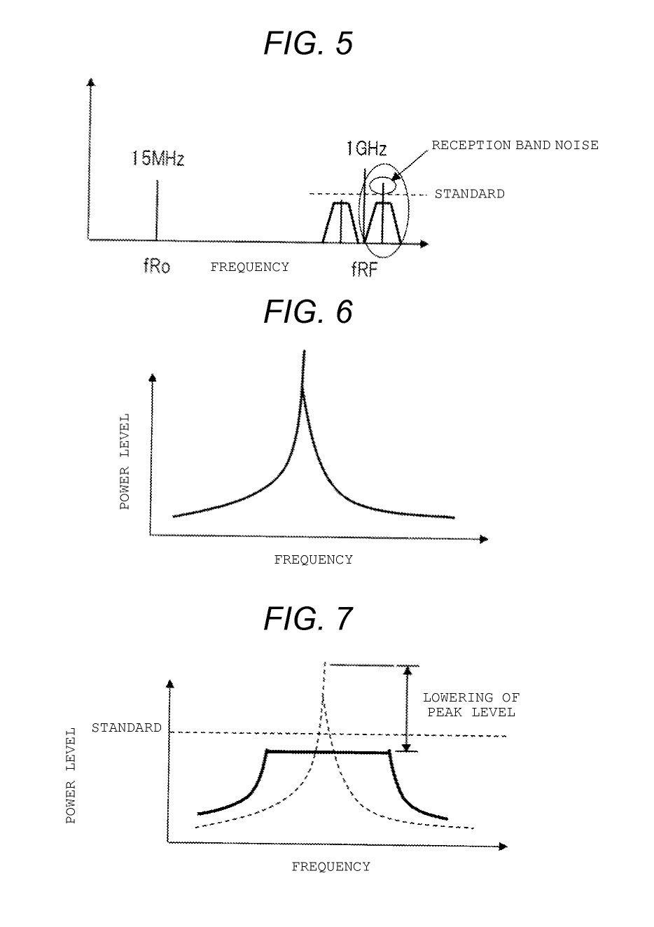

FIG. 5 is a diagram which illustrates the frequency spectrum of each signal in the switching control circuit 1 and the switching circuit 2. Frequency is plotted on the horizontal axis in FIG. 5, and power level is plotted on the vertical axis. In the example in FIG. 5, a transmission signal frequency fRF is set to 1 GHz. For example, in the case of the UMTS system, a bandwidth of 4 MHz is a reception bandwidth, where a frequency higher than a transmission signal frequency by 45 MHz is the center of the bandwidth. The oscillating frequency fR0 of the first oscillating signal which is generated in the first oscillator 21 in FIG. 3 is 15 MHz, for example. When it is assumed that the oscillating frequency of the first oscillating signal is 15 MHz at all times, high harmonic noise of the first oscillating signal occurs at a frequency intervals that are of integral multiples of 15 MHz. Accordingly, as illustrated in FIG. 5, the high harmonic noise overlaps with 1 GHz+45 MHz which is the center frequency in the reception bandwidth. In some cases, there is a concern that a normal reception operation may not be performed since the high harmonic noise exceeds a limit threshold value of a noise level of the UMTS system.

FIG. 6 is a diagram which illustrates frequency spectrum of high harmonic noise when the oscillating frequency of the first oscillating signal is constant. As illustrated, a waveform is obtained where the waveform has a power level that exponentially decreases from the peak value at for example, 15 MHz over a range of integer multiples of the oscillating frequency. For this reason, harmonic noise at 1 GHz+45 MHz, which is the center frequency in the reception bandwidth, becomes a maximum, and there is a concern that high harmonic noise may become larger than a standard value which is determined in UMTS, or the like. This leads to reduction in SN ratio at time of receiving.

In contrast to this, according to the embodiment, the oscillating frequency of the first oscillating signal which is generated in the first oscillator 21 is continuously changed by making the second oscillating signal which is generated in the second oscillator 23 an input to the first oscillator 21. That is, the first oscillator 21 according to the embodiment causes the oscillating frequency of the first oscillating signal to be subject to the spread spectrum. For this reason, as illustrated in FIG. 7, the oscillating frequency of high harmonic wave of the first oscillating signal is spread out over a wide frequency range, and the peak value is also decreased. Therefore, there is no risk that the high harmonic noise of the first oscillating signal exceeds a standard value in the reception bandwidth, the SN ratio at the time of receiving is improved, and reception performance is improved.

Subsequently, a specific method of performing spread spectrum with respect to the oscillating frequency of the first oscillating signal is described. The negative voltage generation circuit 6a in FIG. 4 includes the second oscillator 23 independent from the first oscillator 21. The oscillating frequency of the second oscillating signal generated by the second oscillator 23 is set to be lower than that of the first oscillating signal generated by the first oscillator 21. Accordingly, a signal level of the second oscillating signal is changed with a frequency which is wider than the first oscillating signal. Accordingly, it is possible to make the oscillating frequency of the first oscillating signal which is generated by the first oscillator 21 be continuously variable according to the oscillating frequency of the second oscillating signal, by making the second oscillating signal an input to a predetermined location in the first oscillator 21.

### (First Example of First Oscillator 21)

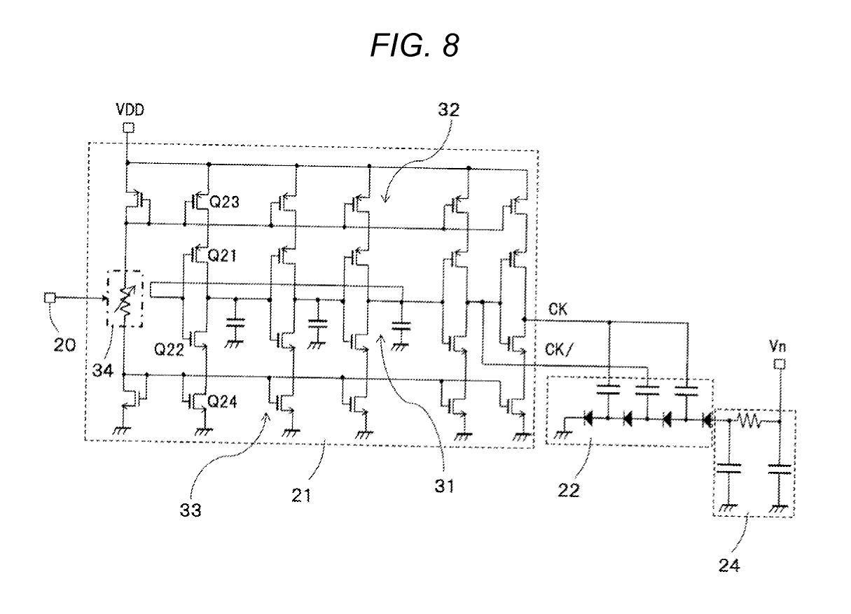

FIG. 8 is a circuit diagram of a first example of an internal configuration of a first oscillator 21. The first oscillator 21 in FIG. 8 includes a first ring oscillator 31 in which n (n is odd number of three or more) inverters are connected in a ring configuration, a first current mirror circuit 32 which is connected to a power supply path on a positive side of each inverter, a second current mirror circuit 33 which is connected to a power supply path on a negative side, and a variable impedance circuit 34 which is connected between the first and second current mirror circuits 32 and 33. The first and second current mirror circuits 32 and 33, and the variable impedance circuit 34 function as a delay control circuit which variably controls a delay time of each inverter in the first ring oscillator 31.

Each inverter includes a PMOS transistor Q21 and an NMOS transistor Q22. A corresponding PMOS transistor Q23 in the current mirror circuit is connected to the PMOS transistor Q21 of each inverter using the cascode connection, and a corresponding NMOS transistor Q24 in the current mirror circuit is connected to the NMOS transistor Q22 of each inverter using the cascode connection.

An impedance of the variable impedance circuit 34 is controlled by a signal which is input to a frequency variable port 20. More specifically, the impedance of the variable impedance circuit 34 is changed according to a voltage level of a signal that is sent to the frequency variable port 20 (control input). The variable impedance circuit 34 may include a variable resistance element, may include a transistor and a variable resistance element, and may include a circuit other than those.

In the first example of the first oscillator 21, the second oscillating signal generated by the second oscillator 23 is sent to the frequency variable port 20. Since the second oscillating signal is a signal whose voltage level is changed using a predetermined oscillating frequency, the impedance of the variable impedance circuit 34 is also continuously changed. When the impedance of the variable impedance circuit 34 is continuously changed, the current that flows in the first and second current mirror circuits 32 and 33 is continuously changed. Owing to this, a current which flows from the power supply path on the positive side to the power supply path on the negative side in each inverter is continuously changed. That is, the delay time in each inverter is continuously changed. When the delay time in each inverter is continuously changed, the oscillating frequency of the first oscillating signal generated in the first oscillator 21 is continuously changed. Accordingly, as illustrated in FIG. 7, frequency spectrum of the first oscillating signal is spread over a wide frequency range.

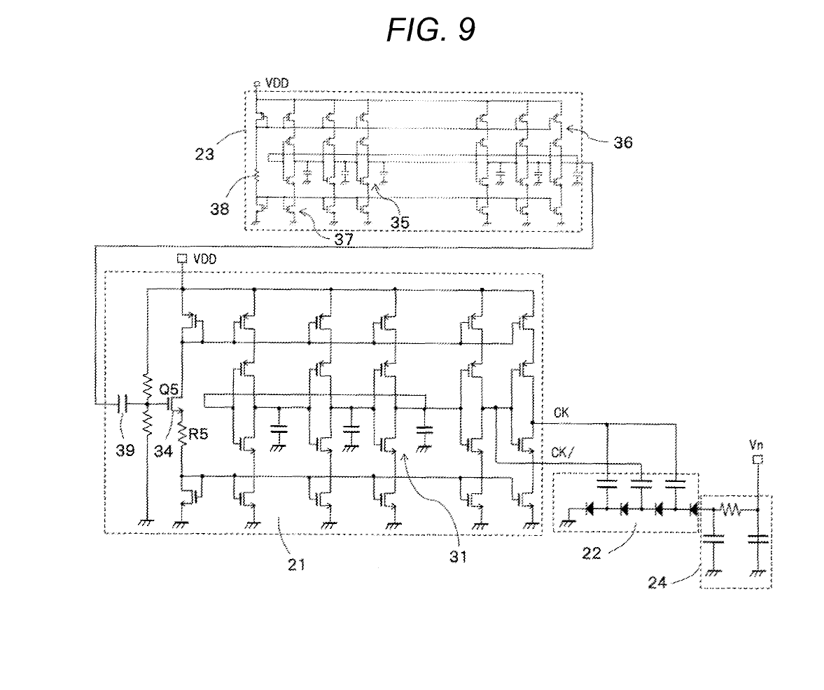

FIG. 9 is a circuit diagram which illustrates an example of an internal configuration of the second oscillator 23. The second oscillator 23 in FIG. 9 includes a second ring oscillator 35 in which m (m is odd number of three or more) inverters are connected in a ring configuration, a third current mirror circuit 36 which is connected to a power supply path on a positive side of each inverter, a fourth current mirror circuit 37 which is connected to a power supply path on a negative side, and an impedance circuit 38 which is connected between the third and fourth current mirror circuits 36 and 37.

Since the oscillating frequency of the second oscillating signal generated in the second oscillator 23 may be fixed, it is not necessary to provide the variable impedance circuit and the frequency variable port in the second oscillator 23. In addition, since the oscillating frequency of the second oscillating signal is lower than that of the first oscillating signal, the number of stages of the inverter of the second ring oscillator 35 maybe set to be larger than those of the first ring oscillator 31 by setting m>n. As an example, the oscillating frequency of the second ring oscillator 35 is set to be approximately 1/10 of the oscillating frequency of the first ring oscillator 31. Alternatively, the oscillating frequency of the second oscillating signal may be set to be lower than that of the first oscillating signal by adjusting a current which flows in a power supply path of each inverter in the second ring oscillator 35, in the third and fourth current mirror circuits 36 and 37.

In FIG. 9, the second oscillating signal generated in the second oscillator 23 is input to the first ring oscillator 31 in the first oscillator 21 through a coupling capacitor 39. The reason for providing the coupling capacitor 39 is to remove DC voltage components. In addition, the variable impedance circuit 34 in the first oscillator 21 in FIG. 8 includes an NMOS transistor Q5 which is connected in series between the first and second current mirror circuits 32 and 33, and an impedance element R1. A drain source resistance of the NMOS transistor is changed according to a signal level of the second oscillating signal, since the second oscillating signal is input to a gate of the NMOS transistor, and due to this, it is possible to cause the current which flows in the first and second current mirror circuits 32 and 33 to be changed continuously.

A signal waveform of the first oscillating signal when the second oscillating signal is input or not input to the frequency variable port 20 in the first oscillator 21 was obtained by using a simulation. In the simulation, the oscillating frequency of the second oscillating signal is set to 400 kHz, and the oscillating frequency of the first oscillating signal when the second oscillating signal is not input to the frequency variable port 20 is set to 4.53 MHz.

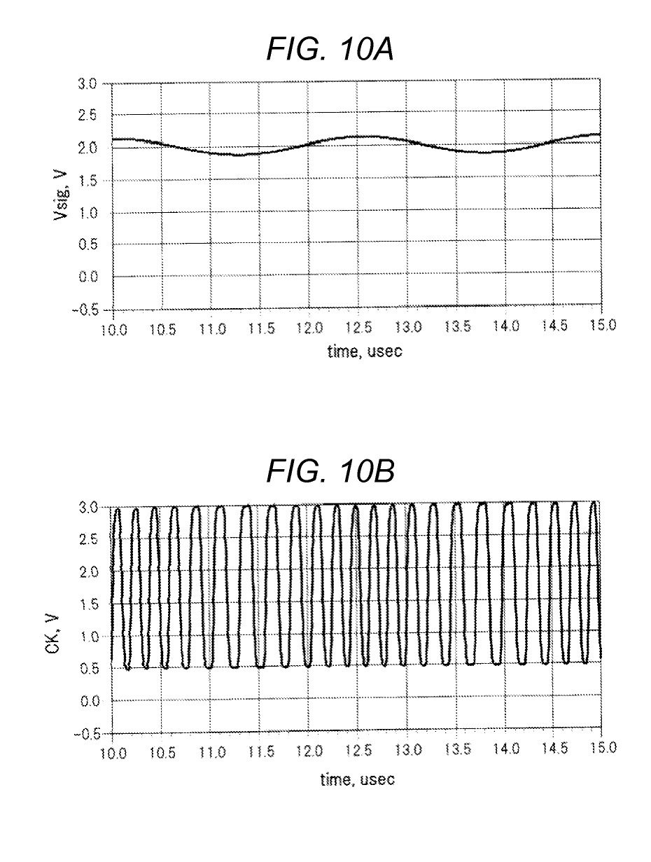

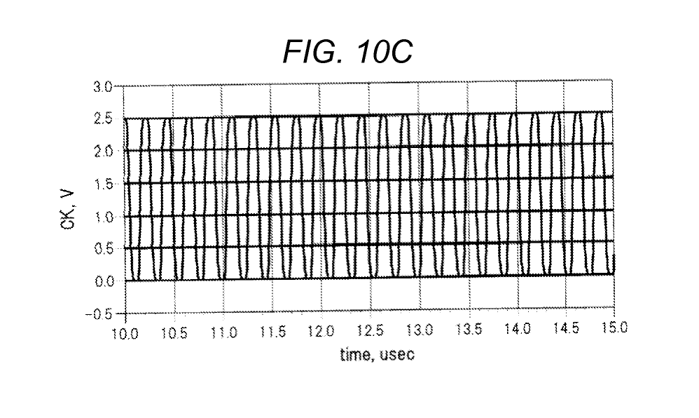

FIGS. 10A to 10C are diagrams of signal waveforms which denote a simulation result, and in which FIG. 10A illustrates a signal waveform of the second oscillating signal, FIG. 10B illustrates a signal waveform of the first oscillating signal when the second oscillating signal is input, and FIG. 10C illustrates a signal waveform of the first oscillating signal when the second oscillating signal is not input.

As is understood when comparing the signal waveforms in FIGS. 10B and 10C with each other, the frequency of the first oscillating signal is modulated according to a change in the signal level of the second oscillating signal when the second oscillating signal is input to the frequency variable port 20, and the oscillating frequency of the first oscillating signal is continuously changed according to a cycle of the second oscillating signal. In this manner, high harmonic components which are generated in the first oscillator 21 are also spread over a wide frequency range, and accordingly, it is possible to entirely suppress a peak level of high harmonic components.

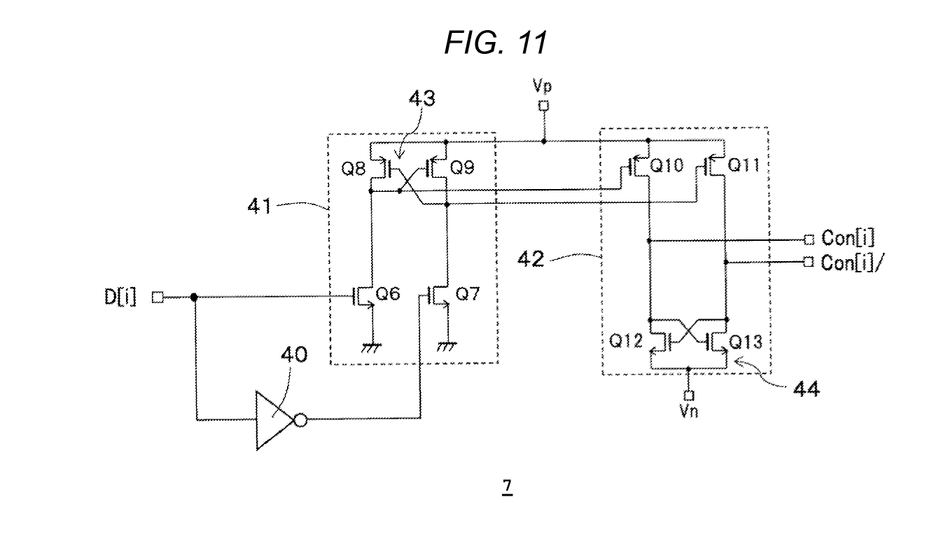

The level shifter 7 in FIG. 3 performs level conversion with respect to the switching control data so that a low level side is a negative voltage. However, a level shifter 7 which performs level conversion in which a high level side becomes a higher step-up voltage may be used. FIG. 11 is a circuit diagram which illustrates an example of the level shifter 7 which makes a power supply voltage on the low level side a negative voltage by stepping up a power supply voltage on the high level side.

The level shifter 7 in FIG. 11 includes an inverter 40, a first stage level conversion unit 41 (a first shifting stage), and a second stage level conversion unit 42 (a second shifting stage). The first stage level conversion unit 41 performs an operation in which a high level signal of the switching control data which is generated in the decoder 4 is raised up to a step-up voltage. The second stage level conversion unit 42 performs an operation in which a low level signal of the switching control data which is generated in the decoder 4 is lowered to a negative voltage.

The first stage level conversion unit 41 includes the voltage holding circuit 43, and two NMOS transistors Q6 and Q7. The voltage holding circuit 43 includes two PMOS transistors Q8 and Q9 each having its gate is connected to the other's drain. Similarly, the second stage level conversion unit 42 includes a voltage holding circuit 44, and two PMOS transistors Q10 and Q11. The voltage holding circuit 44 includes two NMOS transistors Q12 and Q13 each having its gate is connected to the other's drain.

The level shifter 7 in FIG. 3 makes the low level side of the switching control data a negative voltage, however, in contrast to this, since the level shifter 7 in FIG. 11 raises the high level side up to the step-up voltage, in addition to making the low level side of the switching control data the negative voltage, it is possible to generate a switching driving signal with a larger amplitude.

In this manner, a decision as to whether to provide the level shifter 7 in FIG. 3 or the level shifter 7 in FIG. 11 in the driver unit 5 is determined according to a specification of the switching circuit 2 in the second stage.

The step-up voltage in FIG. 11 is generated in a step-up voltage generation circuit which is not illustrated. The step-up voltage generation circuit includes an oscillator, a charge pump, and a filter, similarly to the negative voltage generation circuit 6a in FIG. 3. The oscillator includes two ring oscillators, similar to the first oscillator 21 in FIG. 3, for example, and an oscillating frequency of the first oscillator is continuously changed. Owing to this, even when the level shifter 7 in FIG. 11 is used, there is no risk that high harmonic noise which occurs from the oscillator appears as a high peak in the reception bandwidth.

### (Second Example of First Oscillator 21)

In FIG. 8, the oscillating frequency of the first ring oscillator 31 is continuously changed by adjusting a current which flows in a power supply path of each inverter which configures the first ring oscillator 31 in the first oscillator 21, however, a method of continuously changing the oscillating frequency of the first ring oscillator 31 is not limited to the circuit in FIG. 8.

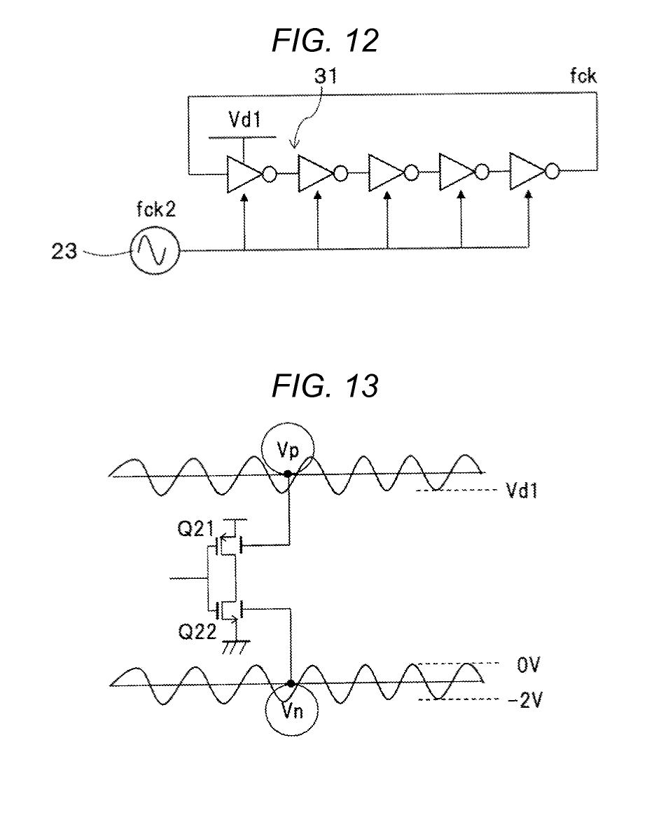

FIG. 12 is a diagram which illustrates a second example of the internal configuration of the first oscillator 21 . The first oscillator 21 in FIG. 12 receives the second oscillating signal generated in the second ring oscillator 35 at an inverter body input in each stage in the first ring oscillator 31.

FIG. 13 is a circuit diagram which illustrates a configuration of an inverter of one stage in the first ring oscillator 31. As is understood from FIG. 13, the inverter in the first ring oscillator 31 includes the PMOS transistor Q21 and the NMOS transistor Q22, and a transistor for the first and second current mirror circuits 32 and 33 illustrated in FIG. 3 is not connected thereto. Instead, the second oscillating signal which is generated in the second ring oscillator 35 is input to bodies of these transistors.

In addition, a minimum signal level of the second oscillating signal which is input to the body of the PMOS transistor Q21 is set to be equal to or greater than a power supply voltage level Vdl of the first ring oscillator 31. For example, it is set such that Vd1=2 V, a minimum voltage of the body is 2 V, and a maximum voltage of the body is 3.5 V.

In addition, a maximum signal level of the second oscillating signal which is input to the body of the NMOS transistor Q22 is set to equal to or smaller than 0 V. For example, a maximum voltage of the body is set to 0 V, and a minimum voltage of the body is set to −2 V.

The oscillating frequency of the second oscillating signal which is generated in the second ring oscillator 35 is set to approximately 1/10 of the oscillating frequency of the first oscillating signal when a body voltage in the first ring oscillator 31 is not adjusted.

In this manner, a body voltage of each inverter in the first ring oscillator 31 moderately fluctuates according to the oscillating frequency of the second oscillating signal. When the body voltage fluctuates, a delay time of each inverter is changed due to a change in a threshold voltage of each inverter, and as a result, the oscillating frequency of the first oscillating signal which is generated in the first oscillator 21 is also continuously changed.

In FIG. 13, the second oscillating signal is input to both the body of the PMOS transistor Q22 and the body of the NMOS transistor Q21 which are included in each inverter in the first ring oscillator 31, however, the second oscillating signal maybe input only to any one of the bodies, and the other body may be connected to a source of a corresponding transistor.

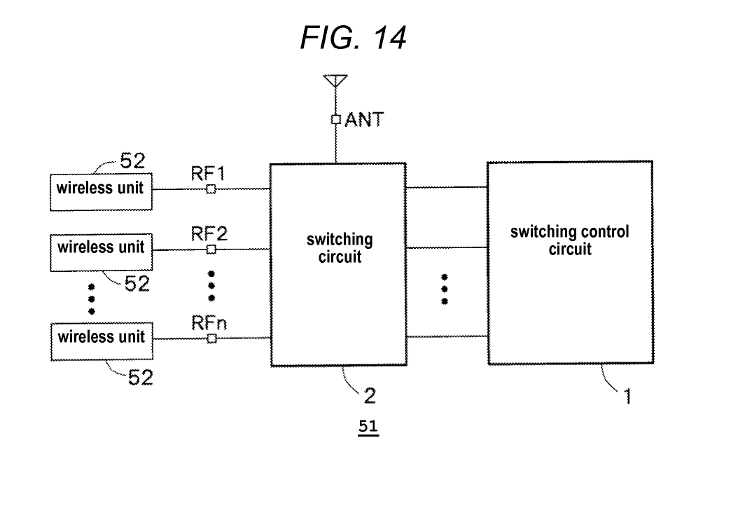

FIG. 14 is a block diagram which illustrates a schematic configuration of a wireless communication device 51 on which the switching control circuit 1 and the switching circuit 2 according to the above described embodiment are mounted. The wireless communication device 51 in FIG. 14 is one of various wireless devices in which a plurality of wireless systems may be used by being switched, such as a mobile phone or a smart phone, and a PC, for example.

The wireless communication device 51 in FIG. 14 includes a plurality of wireless units 52 in which at least one of a frequency bandwidth and a wireless system is different, respectively, and which performs an individual wireless communication, respectively, and the above described switching circuit 2 and the switching control circuit 1 which are connected to the wireless unit 52. These plurality of wireless units 52, the switching circuit 2, and the switching control circuit 1 may be mounted on a support substrate (for example, print wiring substrate) as a separate chip, respectively, or the plurality of wireless units 52, the switching circuit 2, and the switching control circuit 1 may be formed on the same semiconductor substrate. In addition, a plurality of sets of the switching circuit 2 and the switching control circuit 1 maybe provided in the wireless communication device 51.

According to the embodiment, in this manner, since the oscillating frequency of the first oscillating signal which is used for generating the power supply voltage of the level shifter 7 is subject to spread spectrum, it is possible to suppress a signal level with high harmonic components of the first oscillating signal, and to improve the SN ratio in the reception bandwidth.

In particular, since it is possible to achieve the embodiment only by connecting the first ring oscillator 31 which generates the first oscillating signal to a separate second ring oscillator 35, and it is also not necessary to perform complicated adjusting of a circuit parameter, there is no trouble of changing in design from a circuit configuration in the related art.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein maybe made without departing from the spirit of the inventions. The accompanying claims and their equivalents are intended to cover such forms or modifications as would fall within the scope and spirit of the inventions.

What is claimed is:

1. A switching control circuit comprising:
a level shifter configured to generate a switching control signal for a switching circuit; and
a voltage generation circuit that includes
a first oscillator configured to generate a first oscillating signal, wherein a frequency spectrum of the first oscillating signal is subjected to spread spectrum based on a second oscillating signal different from the first oscillating signal; and
a power supply circuit configured to generate a power supply voltage based on the first oscillating signal, and supply a converted power supply voltage to the level shifter.

2. The circuit according to claim 1, further comprising:
a second oscillator configured to generate a second oscillating signal that oscillates with an oscillating frequency lower than an oscillating frequency of the first oscillating signal,
wherein the first oscillator generates the first oscillating signal with the controlled oscillating frequency according to a voltage level of the second oscillating signal.

3. The circuit according to claim 2, wherein the first oscillator includes:
n (n is an odd number of three or more) inverters connected in a ring configuration; and
a delay control circuit configured to control a respective delay time of each of the n inverters according to the voltage level of the second oscillating signal.

4. The circuit according to claim 3, wherein the delay control circuit includes:
a current mirror circuit configured to adjust currents flowing in the n inverters; and
a variable impedance circuit configured to adjust a current flowing in the current mirror circuit according to the voltage level of the second oscillating signal.

5. The circuit according to claim 2, wherein
the first oscillator includes n (n is an odd number of three or more) inverters connected in a ring configuration,
the respective n inverters include two MOS transistors, and
the second oscillating signal is input to at least one of the two MOS transistors.

6. The circuit according to claim 1, wherein the level shifter includes a shifting stage configured to shift a switching control data downward based on the converted power supply voltage.

7. The circuit according to claim 1, wherein the level shifter includes:
a first shifting stage configured to shift switching control data downward based on the converted power supply voltage; and
a second shifting stage configured to shift the switching control data upward based on a high level side power supply voltage.

8. A voltage generation circuit comprising:
a first oscillator configured to generate a first oscillating signal;
a second oscillator configured to supply a second oscillating signal to a control input of the first oscillator such that the frequency of oscillation of the first oscillator varies at a rate dependent on an oscillating frequency of the second oscillating signal; and
a charge pump configured to generate a voltage based on the first oscillating signal of the first oscillator.

9. The circuit according to claim 8, further comprising a filter configured to receive the voltage from the charge pump and output a filtered voltage.

10. The circuit according to claim 8, wherein the first oscillator includes:
n (n is an odd number of three or more) inverters connected in a ring configuration; and
a delay control circuit configured to control a respective delay time of each of the n inverters according to a voltage level of the second oscillating signal.

11. The circuit according to claim 10, wherein the delay control circuit includes:
a current mirror circuit configured to adjust currents flowing in each of the n inverters; and
a variable impedance circuit configured to adjust a current flowing in the current mirror circuit according to the voltage level of the second oscillating signal.

12. The circuit according to claim 8, wherein
the first oscillator includes n (n is an odd number of three or more) inverters connected in a ring configuration,
the respective n inverters include two MOS transistors, and
the second oscillating signal is input to at least one of the two MOS transistors.

13. The circuit according to claim 8, wherein the second oscillator includes:
n (n is an odd number of three or more) inverters connected in a ring configuration; and
a delay control circuit configured to set a respective delay time of each of the n inverters.

14. The circuit according to claim 8, further comprising:
a coupling capacitor,
wherein the second oscillator is connected to the first oscillator through the coupling capacitor.

15. A wireless communication device comprising:
a plurality of wireless units configured to input and output high frequency signals according to different wireless standards;
a switching circuit configured to select one of the plurality of high frequency signals based on a switching control signal; and
a switching control circuit including a level shifter configured to generate a switching control signal for a switching circuit, and a voltage generation circuit, the voltage generation circuit including
a first oscillator configured to generate a first oscillating signal, wherein a frequency spectrum of the first oscillating signal is subjected to spread spectrum; and
a power supply circuit configured to generate a power supply voltage based on the first oscillating signal, and supply a converted power supply voltage to the level shifter.

16. The device according to claim 15, wherein the voltage generation circuit further comprises:
a second oscillator configured to generate a second oscillating signal that oscillates with an oscillating frequency lower than an oscillating frequency of the first oscillating signal,
wherein the first oscillator controls the oscillating frequency of the first oscillating signal according to a voltage level of the second oscillating signal.

17. The device according to claim 16, wherein the first oscillator includes:
n (n is an odd number of three or more) inverters connected in a ring configuration; and
a delay control circuit configured to control a respective delay time of each of the n inverters according to the voltage level of the second oscillating signal.

18. The device according to claim 17, wherein the delay control circuit includes:
a current mirror circuit configured to adjust currents flowing in the n inverters; and
a variable impedance circuit configured to adjust a current flowing in the current mirror circuit according to the voltage level of the second oscillating signal.

19. The device according to claim 16, wherein
the first oscillator includes n (n is an odd number of three or more) inverters connected in a ring configuration,
the respective n inverters include two MOS transistors, and
the second oscillating signal is input to at least one of the two MOS transistors.

20. The device according to claim 15, wherein the level shifter includes:
a first shifting stage configured to shift a switching control data downward based on the converted power supply voltage; and
a second shifting stage configured to shift the switching control data upward based on a high level side power supply voltage.
